(19) United States
(12) Patent Application Publication
(10) Pub. No.: US 2017/0022762 A1
(43) Pub. Date: Jan. 26, 2017

(54) System and method for cleaning of a drill bit

(71) Applicant: Badger Explorer ASA, Stavanger (NO)

(72) Inventors: Oystein Larsen, Stavanger (NO); Sakalima George Sikaneta, Stavanger (NO)

(73) Assignee: Badger Explorer ASA, Stavanger (NO)

(21) Appl. No.: 15/300,806

(22) PCT Filed: Mar. 27, 2015
(86) PCT No.: PCT/EP2015/056813

§ 371 Date: Sep. 30, 2016

(30) Foreign Application Priority Data
Apr. 3, 2014 (NO) 20140432

(51) Int. Cl. E21B 7/24; H03H 9/22; E21B 28/00; H03H 9/15; E21B 10/00; E21B 7/26

(52) U.S. Cl. CPC E21B 7/24; E21B 10/00; E21B 7/26; E21B 28/00; H03H 9/15; H03H 9/22

(57) ABSTRACT

A system for cleaning of a drill bit, comprises a vibration generator arranged to generate vibrations in the ultrasonic frequency range in at least parts of the drill bit, and a power source connected to the vibration generator.

Effective drilling demands the efficient removal of waste rock cuttings and adhesive materials from the face of the drill bit. The challenge of removing waste material from the bit face is particularly severe in conditions in which there is little or no drilling fluid.

For drill tools, for example of the type described in NO312110, this is a particular challenge, as it operates in a closed cavity and must rely solely upon the formation as a source of fluids.

During all drilling, material that is cut by the bit must be transported away from the cutter face (drill bit face). If the cutters become obstructed by waste rock, thick clay, or other spoil from the drilling process, they will cease to function effectively, thus slowing down the drilling process, or in some cases causing the drilling to fail.

U.S. Pat. No. 4,509,593 regards an apparatus for inducing and assisting movement of tools in an oil well, and a piezo electric transducer component for providing ultrasonic energy around the circumference of the apparatus in order to break molecular congealing around the apparatus.

U.S. Pat. No. 7,740,088 describes mechanism for drilling by a combination of sonic hammering and rotation. An ultrasonic/sonic actuator provides vibrations that performs drilling in addition to, or separate from a rotating drill bit.

The object of the invention described in this document is to facilitate the removal of waste material from the face of a drill bit.

The object of the invention is achieved by means of the patent claims.

In one embodiment a system for cleaning of a drill bit comprises a vibration generator arranged to generate vibrations in the ultrasonic frequency range in at least parts of the drill bit, and a power source connected to the vibration generator.

In one embodiment a method for cleaning of drill bit, comprises generating vibrations in at least parts of the drill bit surface in the ultrasonic frequency range.

The ultrasonic frequency range is waves with a frequency of about 20 kHz up to several gigahertz, and even higher. One proposed frequency range that may be used is from 5 kHz to 30 kHz.

Vibrations in this frequency range may for example be produced by means of a vibration generator in the form of a piezoelectric or magnetostrictive transducer. Piezoelectric transducers are devices that convert electrical energy into sound. Piezoelectric crystals have the property of changing size when a voltage is applied, very high frequencies, thus producing very high frequency sound waves, such as in the required frequency range. Similarly magnetostrictive materials can be used for producing the desired vibrations.

In one embodiment the vibration generator is incorporated in the drill bit. In other embodiments, the vibration generator is located at or adjacent to the drill bit, for example together with other equipment or in other parts of the drill.

In one embodiment, a controller unit is connected to the vibration generator to control the vibration generator. The controller unit sets the frequency spectrum of the signal generator, which may be a fixed frequency spectrum, or it may be able to change or have a varying pattern.

It is well established that vibrating a dry or saturated granular mixture will cause a drop in the viscosity of the mixture. The decrease in the resistance to flow is related to the frequency of the vibrations, the size of the particles in the mixture, and the amplitude of the vibrations (Melosh, Journal of Geophysical Research, 1979). The vibration generated in the drill bit makes use of the principle of vibro-fluidization to reduce the flow resistance of the mixture of waste rock in contact with the bit surface. This is achieved through the use of the piezoelectric or magnetostrictive transducer that causes select components of the surface of the bit to vibrate, preferentially at one or more harmonic resonances in the sonic and/or ultrasonic regimes. The use of wide-band excitation is of particular relevance, as this will enable the bit to effectively fluidize cuttings spanning a range of particle sizes. The frequency and amplitude of the vibrations of the vibration generator is in one embodiment selected by the controller unit according to the size of the particles in the mixture of waste rock from the drilling in order to achieve vibro-fluidization.

The parts of the drill bit in which vibrations are generated may for example be flow channels in the bit along which the cuttings are directed, and in the cutters of the bit.

The location at which a transducer focuses the sound can be determined by the active transducer area and shape, the ultrasound frequency, and the sound velocity of the propagation medium.

In one embodiment the vibration generator is arranged to co-rotate with the rotation of the drill bit. This requires that the power connection/electrical connection to the vibration generator are a rotary union or inductive connection. Examples of such connections are rotary electrical connectors, slip rings, brush coupling, etc.

It is also advantageous for the vibratory components to be pressure balanced to the largest degree possible, thus limiting the effects of increasing power requirements as a function of depth and pressure. This may for example be achieved by exposing opposed surfaces of the vibrating device to the environmental pressure.

The described method and device in which the cuttings structures and flow channels of the bit are vibrated the over frequencies spanning the sonic and/or ultrasonic ranges cause the mixture of waste rock and formation fluids in the vicinity of the drill bit to “fluidize”, lowering the mixture's resistance to flow. Due to this effect, the material can be transported more efficiently away from the drill bit.

The invention will now be described in more detail by means of an example and with reference to the accompanying figure.

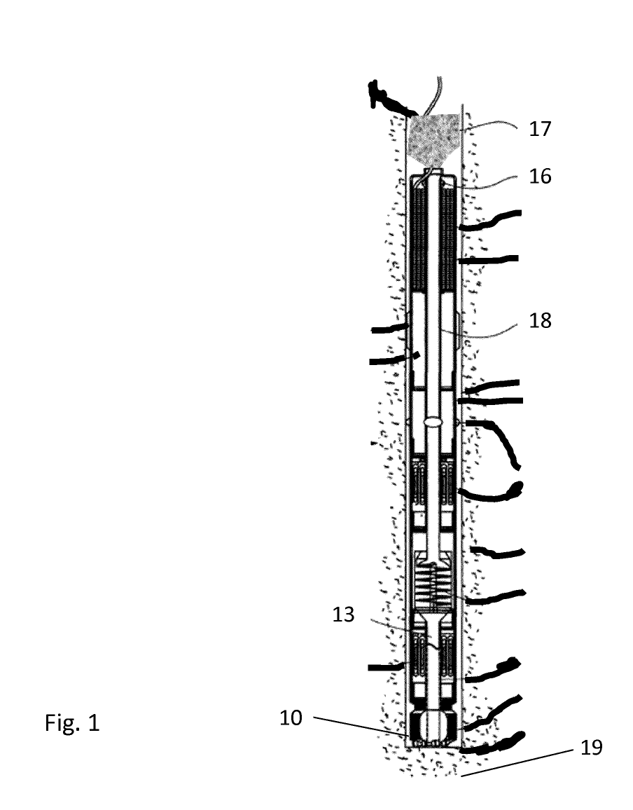

FIG. 1 illustrates an example of an embodiment of a drill bit 10 used in an exploration device, such as the device described in NO312110. As the drill bit 10 drills through a formation 19, it causes rock and any present formation fluids to be released and they will collect around the drill bit 10. The vibration generator is located at or near the drill bit 10 and causes a drop in the viscosity of the rock/cuttings/fluid mixture. The decrease in the resistance to flow causes the cuttings to be guided into an opening in the drill bit and through the opening 13, and further through a pipe 18. Following the drill bit in a transport system of the kind described in NO312110, is a pump or other conveyor means, which causes the cuttings to be transported through the pipe 18 and into a compacting module which compacts the cuttings and deposits the compact cuttings behind the exploration device exiting the pipe at end 16 and deposit behind the device as a mass 17. The drill bit according to the invention may also be used in similar transport systems in other devices.

1. System for cleaning of a drill bit, comprising:
a vibration generator arranged to generate vibrations in the ultrasonic frequency range in at least parts of the drill bit to cause a drop in viscosity of cuttings surrounding the drill bit, and
a power source connected to the vibration generator.

2. System according to claim 1, further comprising a controller unit connected to the vibration generator to control the vibration generator to generate vibrations in a frequency range that will cause vibro-fluidization of the cuttings.

3. System according to claim 1, where the vibration generator is a piezoelectric or magnetostrictive transducer.

4. System according to claim 1, where the vibrations are guided into flow channels in the bit and in the cutters of the bit.

5. System according to claim 1, where the vibrations are in the area 20 kHz and above.

6. System according to claim 1, where the vibration generator is arranged to co-rotate with the rotation of the drill bit.

7. System according to claim 6, where the power source is connected to the vibration generator by means of induction or a rotary union.

8. System according to claim 6, where the vibration generator is incorporated in the drill bit.

9. Method for cleaning of drill bit, comprising:
generating vibrations in at least parts of the drill bit surface in the ultrasonic frequency range to cause a drop in viscosity of cuttings surrounding the drill bit.

10. Method according to claim 9, further comprising controlling the vibration generator a by means of a controller unit connected to the vibration generator to generate vibrations in a frequency range that will cause vibro-fluidization of the cuttings.

11. Method according to claim 9, where the vibration generator is a piezoelectric or magnetostrictive transducer.

12. Method according to claim 9, where the vibrations are generated in flow channels in the bit and in the cutters of the bit.

13. Method according to claim 9, where the vibrations are in the area 20 kHz and above.

14. Method according to claim 9, where the vibration generator co-rotates with the the drill bit.

15. Method according to claim 10, where the controller unit controls the frequency and amplitude of the vibrations of the vibration generator based on the size of the particles

16. Method according to claim 9, where the vibrations causes vibro-fluidization of the waste rock at the surface of the drill bit.
